(19) United States
(12) Patent Application Publication
(10) Pub. No.: US 2021/0185442 A1
(43) Pub. Date: Jun. 17, 2021

(54) AUDIO OUTPUT DEVICE AND PROTECTION METHOD THEREOF

(71) Applicant: Quanta Computer Inc., Taoyuan City (TW)

(72) Inventor: Hsin-Liang LIN, Taoyuan City (TW)

(21) Appl. No.: 16/853,882

(22) Filed: Apr. 21, 2020

(30) Foreign Application Priority Data
Dec. 17, 2019 (TW) 108146085

(51) Int. Cl. H04R 3/00; H03F 1/52

(52) U.S. Cl. CPC H04R 3/007; H03F 2200/03; H04R 2430/01; H03F 1/52

(57) ABSTRACT

An audio output device includes a processor, an audio decoder, an audio amplifier, and a protection circuit. The processor outputs an audio digital signal. The audio decoder converts the audio digital signal into an audio analog signal. The audio amplifier amplifies the audio analog signal. The protection circuit detects abnormalities in the audio digital signal or the amplified audio analog signal. When the audio digital signal or the amplified audio analog signal is abnormal, the protection circuit outputs a disable signal to turn off or mute the audio amplifier, or the protection circuit outputs a logic signal to notify the processor, so that the processor outputs the disable signal to turn off or mute the audio amplifier.

### CROSS REFERENCE TO RELATED APPLICATIONS

This application claims priority to and the benefit of Taiwan Application No. 108146085, filed on Dec. 17, 2019.

### FIELD OF THE INVENTION

The invention relates to an audio output device, especially one relating to an audio output device with a protection circuit having an active protection function.

### DESCRIPTION OF THE RELATED ART

A protection mechanism of an existing audio output device is to detect whether the output voltage or output current of an audio amplifier is excessive, thereby protecting the audio output device. However, existing protection mechanisms have the disadvantages of being expensive and slow, and the protection mechanism must start to operate when the voltage or current output by the audio amplifier is too large (such as short circuit overcurrent protection or overvoltage protection), which is a passive protection method. When an electronic device suffers a crash, since the processor of the electronic device continues to send signals to the audio amplifier, the audio amplifier cannot be protected or turned off.

### BRIEF SUMMARY OF THE INVENTION

In order to resolve the issue described above, an embodiment of the invention provides an audio output device, including a processor, an audio decoder, an audio amplifier, and a protection circuit. The processor is configured to output the audio digital signal. The audio decoder is configured to convert the audio digital signal to an audio analog signal. The audio amplifier is configured to amplify the audio analog signal. The protection circuit is configured to detect whether the audio digital signal or the amplified audio analog signal is abnormal or not. When the audio digital signal or the amplified audio analog signal is abnormal, the protection circuit outputs a disable signal to turn off or mute the audio amplifier, or the protection circuit outputs a logic signal to notify the processor, so that the processor outputs the disable signal to turn off or mute the audio amplifier.

According to the audio output device disclosed above, further comprising a speaker; wherein the speaker receives the amplified audio analog signal, and converts the amplified audio analog signal into a sound.

According to the audio output device disclosed above, wherein the audio digital signal is transmitted through an I²S communication protocol, the I²S communication protocol comprises a word select line, a bit clock line, and a data line. The word select line is configured to transmit a left-right clock (LRCK) to indicate a left channel audio or a right channel audio. The bit clock line is configured to transmit a bit clock (BCK). The data line is configured to transmit a data signal carried by the audio digital signal.

According to the audio output device disclosed above, wherein the protection circuit comprising an AND gate circuit, a watch dog circuit, or a signal filter circuit. When the AND gate circuit detects that the left-right clock, the bit clock, or the data signal is not output, the AND gate circuit outputs a disable signal to the audio amplifier or outputs the logic signal to notify the processor. When the watch dog circuit detects that the bit clock is not output, the watch dog circuit outputs a disable signal to the audio amplifier or outputs the logic signal to notify the processor. The signal filter circuit converts the audio digital signal into a voltage signal according to the duty cycle of the audio digital signal. When the voltage signal is higher than the upper limit voltage value or lower than the lower limit voltage value, the filter circuit outputs a disable signal to the audio amplifier or outputs the logic signal to notify the processor.

According to the audio output device disclosed above, further comprising a processor configured to turn off or mute the audio amplifier according to the logic signal, and configured to show an abnormal message of the audio output device on a display through an operating system (OS).

An embodiment of the invention provides a power switching system, comprising a protection method of an audio output device, wherein the audio output device comprises a processor and an audio amplifier. The protection method comprising: retrieving an audio digital signal; converting the audio digital signal into an audio analog signal; amplifying the audio analog signal; detecting whether the audio digital signal or the amplified audio analog signal is abnormal or not; when the audio digital signal or the amplified audio analog signal is abnormal, outputting a disable signal to turn off or mute the audio amplifier, or outputting a logic signal to notify the processor, so that the processor outputs the disable signal to turn off or mute the audio amplifier. The audio digital signal comprises a left-right clock, a bit clock, and a data signal.

### BRIEF DESCRIPTION OF THE DRAWINGS

The invention can be more fully understood by reading the subsequent detailed description with references made to the accompanying figures. It should be understood that the figures are not drawn to scale in accordance with standard practice in the industry. In fact, it is allowed to arbitrarily enlarge or reduce the size of components for clear illustration.

FIG. 1 shows a block diagram of an audio output device 100 in accordance with some embodiments of the disclosure.

FIG. 2 shows a block diagram of an audio output device 200 having an AND gate circuit as a protection circuit in accordance with some embodiments of the disclosure.

FIG. 3 shows a block diagram of an audio output device 300 having a watch dog circuit as the protection circuit in accordance with some embodiments of the disclosure.

FIG. 4A shows a block diagram of an audio output device 400 having a signal filter circuit as the protection circuit in accordance with some embodiments of the disclosure.

FIG. 4B shows a schematic diagram of the signal filter circuit in accordance with some embodiments of the disclosure.

FIG. 5 shows a flow chart of a protection method of the audio output device in accordance with some embodiments of the disclosure.

### DETAILED DESCRIPTION OF THE INVENTION

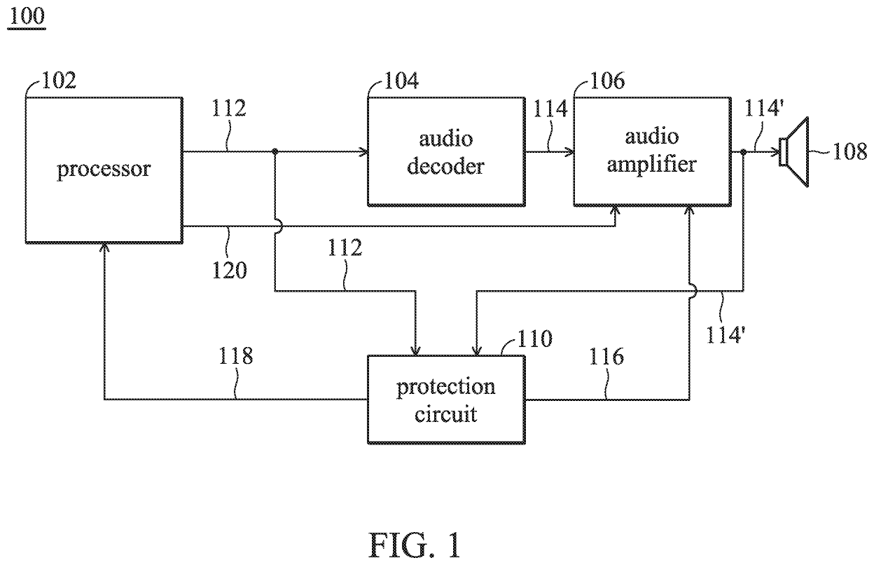

FIG. 1 shows a block diagram of an audio output device 100 in accordance with some embodiments of the disclosure. As shown in FIG. 1, the audio output device 100 includes a processor 102, an audio decoder 104, an audio amplifier 106, a speaker 108, and a protection circuit 110. The processor 102 may be a central processing unit in a desktop computer, a laptop computer, a smart phone, or a workstation server to execute a program that the user wants to execute. In some embodiments, the processor 102 may output an audio digital signal. For example, when the user wants to play music file for listening to music through operation of the operating system, the processor 102 outputs an audio digital signal corresponding to the content of the music file to the audio decoder 104 according to the music file. In some embodiments, the processor 102 may transmit the audio digital signal 112 to the audio decoder 104 by using an Inter-IC Sound (I²S) communication protocol. The I²S communication protocol includes a word select line, a bit clock line, and a data line. The word select line is configured to transmit a left-right clock (LRCK) to indicate that the data transmitted by the I²S communication protocol belong to a left channel or a right channel. The bit clock line is configured to transmit a bit clock. The data line (or serial data line) is configured to transmit a data signal carried by the audio digital signal. The transmission of the data signal is synchronized with the bit clock. In other words, when the audio digital signal 112 is transmitting the data signal through the data line, the audio digital signal 112 also transmits the bit clock synchronized with the timing of the data signal through the bit clock line, and the audio digital signal 112 also transmits the left-right clock through the word select line to indicate whether the currently transmitted data signal belongs to the left channel or the right channel.

In some embodiments, after the audio decoder 104 receives the audio digital signal 112 from the processor 102, the audio decoder 104 converts the audio digital signal 112 into an audio analog signal 114, and outputs the audio analog signal 114 to the audio amplifier 106. In other words, the audio decoder 104 may include an analog-to-digital converter (ADC) to convert the audio digital signal 112 into an audio analog signal 114. After the audio amplifier 106 receives the audio analog signal 114 from the audio decoder 104, the audio amplifier 106 then amplifies the audio analog signal 114 to generate an amplified audio analog signal 114′. The amplified audio analog signal 114′ is then transmitted to the speaker 108, whereupon the speaker 108 converts the amplified audio analog signal 114′ into a corresponding sound and plays it, so that the user can listen to the music in the music file.

In some embodiments, as shown in FIG. 1, the protection circuit 110 may detect whether the audio digital signal 112 or the amplified audio analog signal 114′ is abnormal or not. For example, the protection circuit 110 may detect whether at least one of the left-right clock, the bit clock, and the data signal is not output (for example, the system is shut down or the audio decoder is abnormal or damaged, which can cause a disconnection or short circuit), or detect whether a communication packet format of the at least one of the left-right clock, the bit clock, and the data signal is incorrect. When the audio digital signal 112 or the amplified audio analog signal 114′ is abnormal, the protection circuit 110 outputs a disable signal 116 to turn off or mute the audio amplifier 106, or the protection circuit 110 outputs a logic signal 118 to notify the processor 102, so that the processor 102 outputs a disable signal 120 to turn off or mute the audio amplifier. For example, when the protection circuit 110 detects that the left-right clock, the bit clock, or the data signal of the audio digital signal 112 is not output or its data format is not correct, the protection circuit 110 may directly output the disable signal 116 to the audio amplifier 106 to turn off or mute the audio amplifier 106. In some embodiments, since the protection circuit 110 can directly turn off or mute the audio amplifier 106, even when the processor 102 is in a shutdown state, the protection circuit 110 can still turn off or mute the audio amplifier 106 independently. In some embodiments, when the protection circuit 110 detects that the left-right clock, the bit clock, or the data signal of the audio digital signal 112 is not output or its data format is not correct, the protection circuit 110 may output the logic signal 118 to the processor 102. After the processor 102 receives the logic signal 118, the processor 102 then outputs the disable signal 120 to the audio amplifier 106 to turn off or mute the audio amplifier 106.

In addition, the protection circuit 110 is able to detect whether the amplified audio analog signal 114′ is abnormal or not. For example, when the audio decoder 104 fails, the audio analog signal 114 output in accordance with the audio digital signal 112 may have a DC component. The abnormal audio analog signal 114 is amplified by the audio amplifier 106 to become an amplified audio analog signal 114′ with the DC component. When the amplified audio analog signal 114′ with the DC component is output to the speaker 108, the DC component flows through a coil of the speaker 108, a large current is generated and the speaker 108 may be burned. Therefore, in some embodiments, the protection circuit 110 may also detect whether the amplified audio analog signal 114′ is abnormal or not. When the amplified audio analog signal 114′ is abnormal, the protection circuit 110 may output the disable signal 116 to turn off or mute the audio amplifier 106, or the protection circuit 110 may output the logic signal 118 to notify the processor 102, so that the processor 102 outputs the disable signal 120 to turn off or mute the audio amplifier 106. In some embodiments, the disable signal 116, the logic signal 118, and the disable signal 120 may be a logic low level signal (such as “0”) or a logic high level signal (such as “1”).

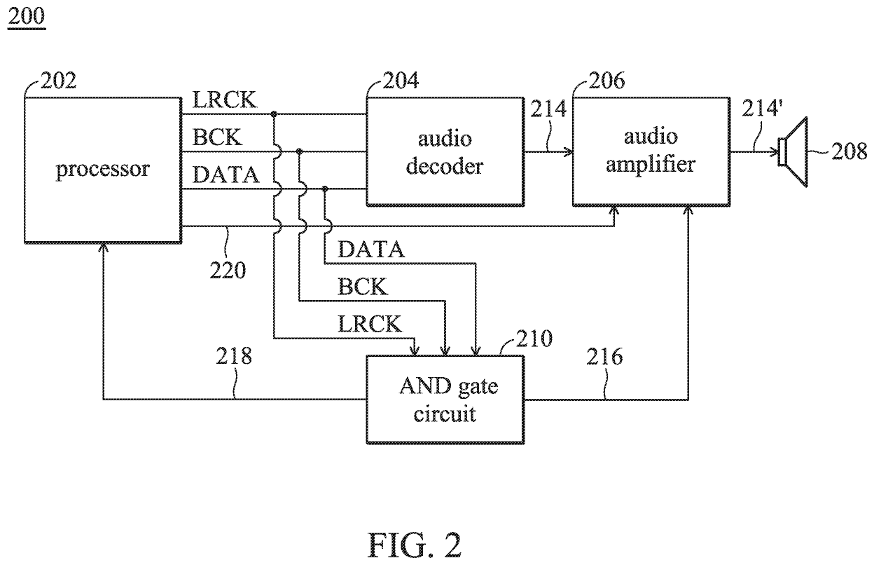

In some embodiments, the protection circuit 110 includes an AND gate circuit, a watch dog circuit, and a signal filter circuit. FIG. 2 shows a block diagram of an audio output device 200 having an AND gate circuit as a protection circuit in accordance with some embodiments of the disclosure. As shown in FIG. 2, the audio output device 200 includes a processor 202, an audio decoder 204, an audio amplifier 206, a speaker 208, and an AND gate circuit 210. The audio output device 200 is different from the audio output device 100 in FIG. 1 in that the audio output device 200 has the AND gate circuit 210 to replace the protection circuit 110 of the audio output device 100. Furthermore, the audio output device 200 has a left-right clock (LRCK), a bit clock (BCK), and a data signal (DATA) to replace the audio digital signal 112 of the audio output device 100. The audio decoder 204 coverts the left-right clock (LRCK), the bit clock (BCK), and the data signal (DATA) output from the processor 202 to an audio analog signal 214, and the audio amplifier 206 then amplifies the audio analog signal 214 to generate an amplified audio analog signal 214′ and transmits it to the speaker 208. The AND gate circuit 210 is able to detect whether the left-right clock (LRCK), the bit clock (BCK), or the data signal (DATA) is abnormal or not. The AND gate circuit 210 may include a capacitor connected to a ground, and at least one AND gate circuit. The capacitor connected to the ground can respectively convert the left-right clock (LRCK), the bit clock (BCK), and the data signal (DATA) to a DC voltage signal, and the voltage level of the DC voltage signal respectively depends on duty cycles of the left-right clock (LRCK), the bit clock (BCK), and the data signal (DATA). For example, at the current time point, the AND gate circuit 210 only detects that the left-right clock (LRCK) and the bit clock (BCK) are output, but the data signal (DATA) is not output. At this time, the left-right clock (LRCK) and the bit clock (BCK) are converted to a voltage signal greater than a threshold voltage through the capacitor connected to the ground, the AND gate circuit 210 therefore determines that the left-right clock (LRCK) and the bit clock (BCK) are logic high level “1”. The data signal (DATA) is converted to a voltage signal lower than the threshold voltage through the capacitor connected to the ground, the AND gate circuit 210 therefore determines that the data signal (DATA) is logic low level “0”. The result of performing an AND calculation of the above three signals may get a logic low level “0”. When the result of AND calculation is the logic low level “0”, the AND gate circuit 210 is configured to output a disable signal 216 to the audio amplifier 206, or output a logic signal 218 to the processor 202. After the processor 202 receives the logic signal 218, the processor 202 may correspondingly outputs a disable signal 220 to the audio amplifier 206 to turn off or mute the audio amplifier 206.

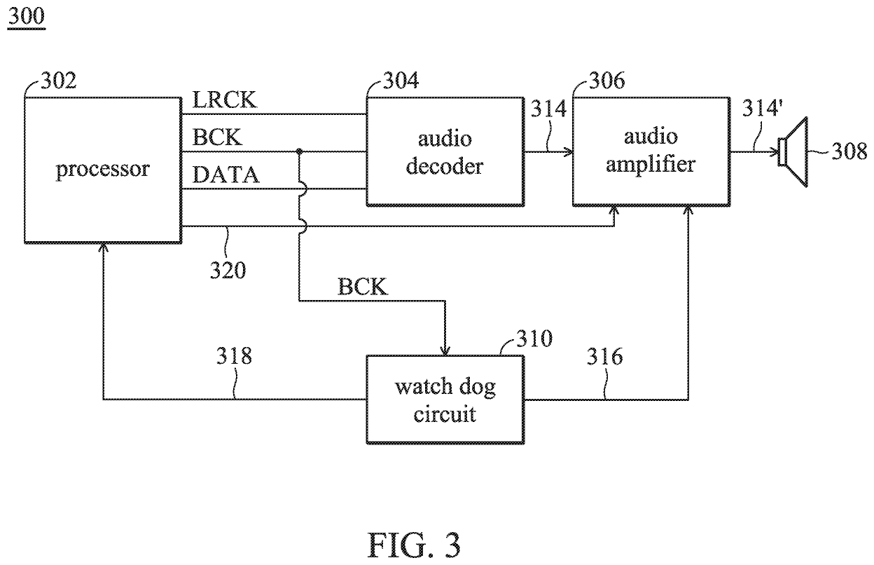

FIG. 3 shows a block diagram of an audio output device 300 having a watch dog circuit as the protection circuit in accordance with some embodiments of the disclosure. As shown in FIG. 3, the audio output device 300 includes a processor 302, an audio decoder 304, an audio amplifier 306, a speaker 308, and a watch dog circuit 310. The audio output device 300 is different from the audio output device 200 in FIG. 2 in that the audio output device 300 has the watch dog circuit 310 to replace the AND gate circuit 210 of the audio output device 200, and the watch dog circuit 310 only detects whether the bit clock (BCK) is abnormal or not, but the present invention is not limited thereto. Same as the audio output devices 100 and 200, the audio decoder 304 in the audio output device 300 converts the left-right clock (LRCK), the bit clock (BCK), and the data signal (DATA) output from the processor 302 into an audio analog signal 314, and the audio amplifier 306 then amplifies the audio analog signal 314 to generate an amplified audio analog signal 314′ and transmits it to the speaker 308. In some embodiments, the watch dog circuit 310 is able to detect whether the bit clock (BCK) is abnormal or not, but the present invention is not limited thereto. For example, when the frequency of the bit clock (BCK) output by the processor 302 is inaccurate, or the bit clock (BCK) is not output, the watch dog circuit 310 may directly output a disable signal 316 to turn off or mute the audio amplifier 306 to avoid the audio amplifier 306 amplifying the incorrect audio analog signal 314 (for example, having a DC component) and transmitting it to the speaker 308, causing permanent damage to the speaker 308. In some embodiments, when the bit clock output from the processor 302 is abnormal, the watch dog circuit 310 may output a logic signal 318 to the processor 302, and the processor 302 may output a disable signal 320 to turn off or mute the audio amplifier 306.

In some embodiments, the watch dog circuit 310 may include a frequency-voltage converting circuit (not shown) to linearly convert the frequency of the received bit clock to a voltage signal. In other words, the higher the frequency of the received bit clock (BCK) is, the higher the voltage of the voltage signal, and vice versa. For example, when the bit clock (BCK) is not output, the frequency-voltage converting circuit of the watch dog circuit 310 generates a voltage 0V according to the frequency of the bit clock (BCK) (the frequency is 0). The watch dog circuit 310 determines the bit clock (BCK) is abnormal according to the voltage 0V, thus correspondingly outputs the disable signal 316 or the logic signal 318 to directly or indirectly turn off or mute the audio amplifier 306.

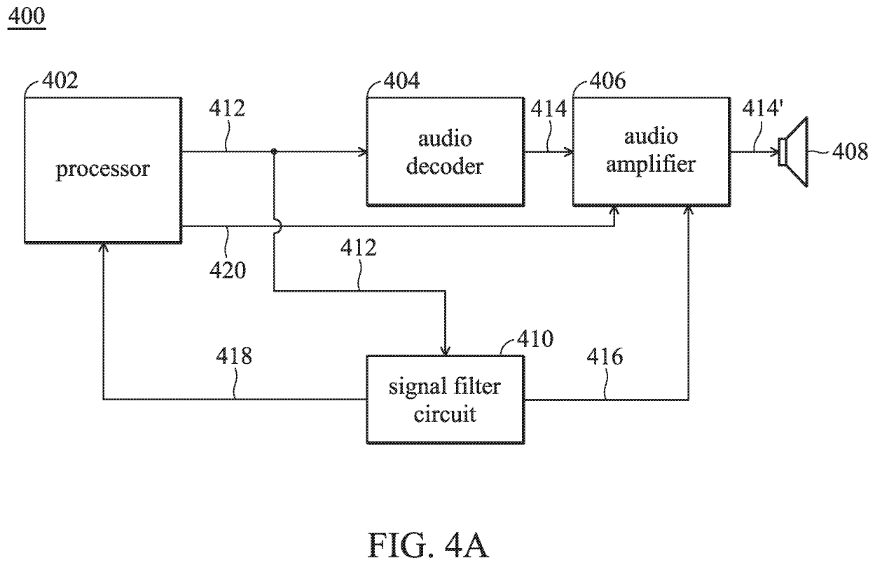

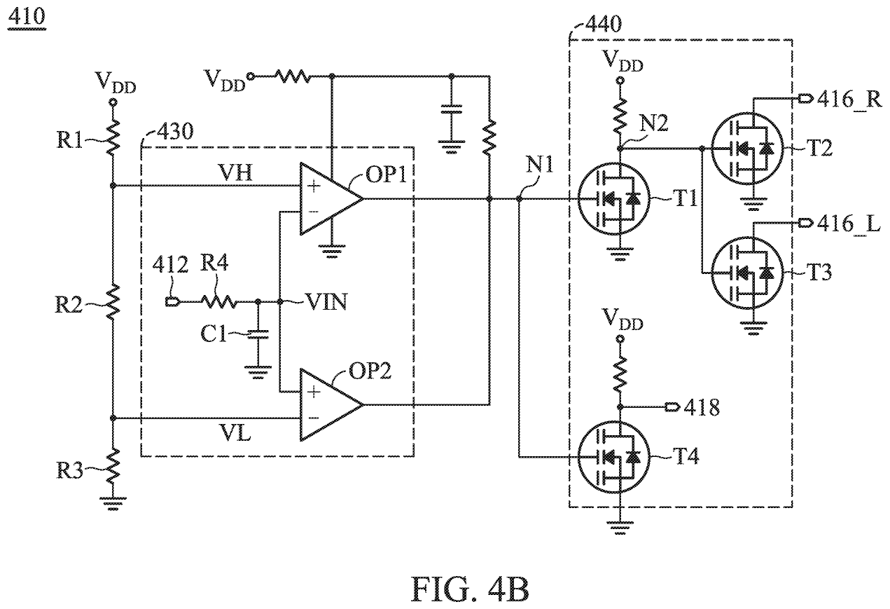

In some embodiments, the protection circuit 110 of the audio output device 100 in FIG. 1 can be designed as a signal filter circuit. FIG. 4A shows a block diagram of an audio output device 400 having a signal filter circuit as the protection circuit in accordance with some embodiments of the disclosure. As shown in FIG. 4A, the audio output device 400 includes a processor 402, an audio decoder 404, an audio amplifier 406, a speaker 408, and a signal filter circuit 410. The audio output device 400 is different from the audio output device 100 in FIG. 1 in that the audio output device 400 has the signal filter circuit 410 to replace the protection circuit 110 of the audio output device 100, and the signal filter circuit 410 only detects an audio digital signal 412, but does not detect an amplified audio analog signal 414′ amplified by the audio amplifier 406. Same as the audio output device 100, the audio decoder 404 in the audio output device 400 coverts the audio digital signal 412 output from the processor 402 to an audio analog signal 414, and the audio amplifier 406 amplifies the audio analog signal 414 to generate the amplified audio analog signal 414′, and transmits it to the speaker 408. When the signal filter circuit 410 detects that the audio digital signal 412 is abnormal, the signal filter circuit 410 outputs a disable signal 416 to the audio amplifier 406, or outputs a logic signal 418 to the processor 402 to directly or indirectly turn off or mute the audio amplifier 406.

FIG. 4B shows a schematic diagram of the signal filter circuit in accordance with some embodiments of the disclosure. As shown in FIG. 4B, the signal filter circuit 410 includes a comparator 430 and a logic circuit 440. The comparator 430 receives the audio digital signal 412, and filters the high frequency component of the audio digital signal 412 through a low pass filter composed of a resistor R4 and a capacitor C1. Therefore, the comparator 430 can convert the audio digital signal 412 to a voltage signal (VIN) according to the duty cycle of the audio digital signal 412, the voltage signal (VIN) is then transmitted to a negative input end (−) of an operational amplifier OP1 and a positive input end (+) of an operational amplifier OP2. A power supply voltage VDD generates an upper limit voltage (VH) inputting to the positive input end (+) of the operational amplifier OP1 through the voltage division of resistors R1, R2, and R3, and generates a lower limit voltage (VL) inputting to the negative input end (−) of the operational amplifier OP2 through the voltage division of resistors R1, R2, and R3. When the voltage signal (VIN) is higher than the upper limit voltage (VH), the operational amplifier OP1 outputs a low level voltage. When the voltage signal (VIN) is lower than the lower limit voltage (VL), the operational amplifier OP2 outputs a low level voltage. When the voltage signal (VIN) is between the upper limit voltage (VH) and the lower limit voltage (VL), the operational amplifiers OP1 and OP2 both output a high level voltage, so that the voltage at a node N1 is at a high level. In other words, as long as the duty cycle of the audio digital signal 412 is within a preset range. That is, the audio digital signal 412 is output normally and the voltage at the node N1 will be at the high level. In contrast, if the audio digital signal 412 is output abnormally, the voltage at the node N1 will be at a low level.

Then, the voltage at the node N1 is an input of the logic circuit 440. When the voltage at the node N1 is at the high level (the audio digital signal 412 is output normally), a transistor T1 is turned on, so that the voltage at a node N2 is at the low level. Since the voltage at the node N2 is at the low level, transistors T2 and T3 is turned off, so that a disable signals 416_R and 416_L are maintained in a floating state without being pulled to the low level. The disable signals 416_R and 416_L are connected to the audio amplifier 406 to turn off or mute the right and left channels of the audio amplifier 406. In some embodiments, the disable signals 416_R and 416_L need to be at the low level to turn off or mute the audio amplifier 406, but the present invention is not limited thereto. In other words, according to the present invention, a person skilled in the art can also design the disable signals 416_R and 416_L so that they need to be at the high level to turn off or mute the audio amplifier 406. When the voltage at the node N1 is at the high level, a transistor T4 is turned on, so that the logic signal 418 is at a low level. The logic signal 418 is connected to the processor 402 to notify the processor 402 whether to turn off or mute the audio amplifier 406 or not. In some embodiments, the logic signal 418 needs to be at the high level to enable the processor 402 to output a disable signal 420 to turn off or mute the audio amplifier 406. Thus, when the voltage at the node N1 is at the high level and the logic signal 418 is at the low level, the processor 402 will not output the disable signal 420, but the present invention is not limited thereto.

When the voltage at the node N1 is at the low level (the audio digital signal is output abnormally), the transistor T1 is turned off, the voltage at the node N2 is at the high level, so that transistors T2 and T3 are both turned on, thus the disable signals 416_R and 416_L become at the low level. In some embodiments, since the disable signals 416_R and 416_L are at the low level, the signal filter circuit 410 turns off or mute the audio amplifier 406. When the voltage at the node N1 is at the low level, the transistor T4 is turned off, the logic signal 418 is maintained at the high level. In some embodiments, since the logic signal 418 is at the high level, the processor 402 outputs the disable signal 420 to turn off or mute the audio amplifier 406, but the present invention is not limited thereto.

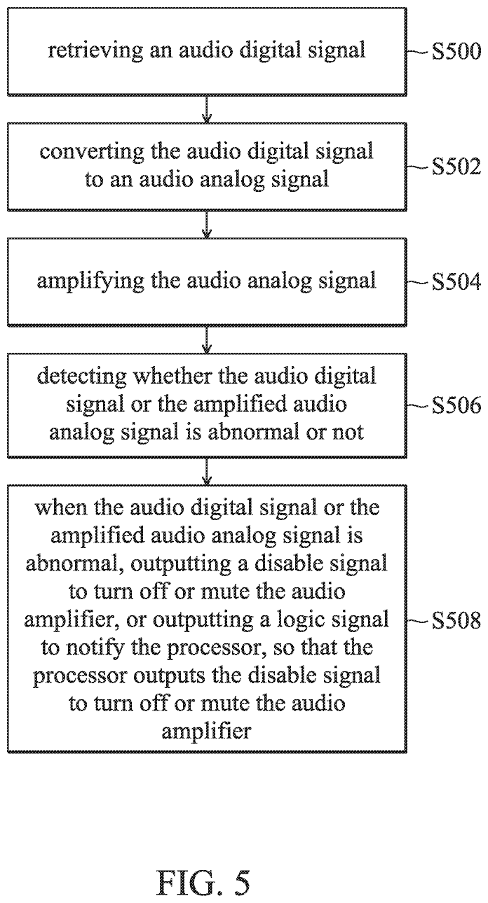

The present invention also discloses a protection method of an audio output device, wherein the audio output device includes a processor and an audio amplifier. FIG. 5 shows a flow chart of a protection method of the audio output device in accordance with some embodiments of the disclosure. As shown in FIG. 5, the protection method of the audio output device includes retrieving an audio digital signal (step S500); converting the audio digital signal into an audio analog signal (step S502); amplifying the audio analog signal (step S504); detecting whether the audio digital signal or the amplified audio analog signal is abnormal or not (step S506); and when the audio digital signal or the amplified audio analog signal is abnormal, outputting a disable signal to turn off or mute the audio amplifier, or outputting a logic signal to notify the processor, so that the processor outputs the disable signal to turn off or mute the audio amplifier (step S508). The audio digital signal described in the step S500 includes a left-right clock, a bit clock and a data signal.

The protection method of the audio output device further includes that when detecting the left-right clock, the bit clock, or the data signal is not output, outputting the disable signal to the audio amplifier, or outputting the logic signal to notify the processor. The protection method of the audio output device further includes converting the audio digital signal into a voltage signal according to the duty cycle of the audio digital signal, and when the voltage signal is higher than an upper limit voltage or lower than a lower limit voltage, then outputting the disable signal to the audio amplifier, or outputting the logic signal to notify the processor.

The present invention uses an active detection to detect whether an input end of the audio amplifier is abnormal, and turns off an output end of the audio amplifier when an abnormality occurs, so as to protect the audio amplifier and avoid burning the speaker or outputting abnormal audio. A person skilled in the art will understand that the audio amplifier in an audio output device is one of the most power-consuming components during operation. Therefore, the present invention uses a protection circuit with an active pre-detection of abnormality to turn off the audio amplifier when an abnormality occurs. At the same time, it also has a power-saving effect. After waiting for abnormal conditions to be resolved, the audio output device of the present invention can recover the normal audio output, which is obviously different from the passive protection mechanism in the prior art that waits for the output terminal of the audio amplifier to be abnormal.

The ordinals in the specification and the claims of the present invention, such as “first”, “second”, “third”, etc., have no sequential relationship, and are just for distinguishing between two different components with the same name. In the specification of the present invention, the word “couple” refers to any kind of direct or indirect electronic connection. The present invention is disclosed in the preferred embodiments as described above, however, the breadth and scope of the present invention should not be limited by any of the embodiments described above. Persons skilled in the art can make small changes and retouches without departing from the spirit and scope of the invention. The scope of the invention should be defined in accordance with the following claims and their equivalents.

What is claimed is:

1. An audio output device, comprising:
a processor, configured to output an audio digital signal;
an audio decoder, configured to convert the audio digital signal into an audio analog signal;
an audio amplifier, configured to amplify the audio analog signal;
a protection circuit, configured to detect whether the audio digital signal or the amplified audio analog signal is abnormal or not;
when the audio digital signal or the amplified audio analog signal is abnormal, the protection circuit outputs a disable signal to turn off or mute the audio amplifier, or the protection circuit outputs a logic signal to notify the processor, so that the processor outputs the disable signal to turn off or mute the audio amplifier.

2. The audio output device as claimed in claim 1, further comprising a speaker;
wherein the speaker receives the amplified audio analog signal, and converts the amplified audio analog signal into a sound.

3. The audio output device as claimed in claim 1, wherein the audio digital signal is transmitted through an I²S communication protocol, the I²S communication protocol comprising:
a word select line, configured to transmit a left-right clock (LRCK) to indicate a left channel or a right channel;
a bit clock line, configured to transmit a bit clock (BCK); and
a data line, configured to transmit a data signal carried by the audio digital signal.

4. The audio output device as claimed in claim 3, wherein the protection circuit comprises an AND gate circuit, a watch dog circuit, or a signal filter circuit.

5. The audio output device as claimed in claim 4, wherein when the AND gate circuit detects that the left-right clock, the bit clock, or the data signal is not output, the AND gate circuit outputs a disable signal to the audio amplifier or outputs the logic signal to notify the processor.

6. The audio output device as claimed in claim 4, wherein when the watch dog circuit detects that the bit clock is not output, the watch dog circuit outputs a disable signal to the audio amplifier or outputs the logic signal to notify the processor.

7. The audio output device as claimed in claim 4, wherein the signal filter circuit converts the audio digital signal into a voltage signal according to a duty cycle of the audio digital signal; when the voltage signal is higher than an upper limit voltage value or lower than a lower limit voltage value, the filter circuit outputs a disable signal to the audio amplifier or outputs the logic signal to notify the processor.

8. The audio output device as claimed in claim 5, further comprising a processor configured to turn off or mute the audio amplifier according to the logic signal, and configured to show an abnormal message of the audio output device on a display through an operating system (OS).

9. The audio output device as claimed in claim 6, further comprising a processor configured to turn off or mute the audio amplifier according to the logic signal, and configured to show an abnormal message of the audio output device on a display through an operating system (OS).

10. The audio output device as claimed in claim 7, further comprising a processor configured to turn off or mute the audio amplifier according to the logic signal, and configured to show an abnormal message of the audio output device on a display through an operating system (OS).

11. A protection method of an audio output device, wherein the audio output device comprises a processor and an audio amplifier, the protection method comprising:
retrieving an audio digital signal;
converting the audio digital signal into an audio analog signal;
amplifying the audio analog signal;
detecting whether the audio digital signal or the amplified audio analog signal is abnormal or not;
when the audio digital signal or the amplified audio analog signal is abnormal, outputting a disable signal to turn off or mute the audio amplifier, or outputting a logic signal to notify the processor, so that the processor outputs the disable signal to turn off or mute the audio amplifier.

12. The protection method as claimed in claim 11, wherein the audio digital signal comprises a left-right clock, a bit clock, and a data signal.
